(19) United States
(12) Patent Application Publication
(10) Pub. No.: US 2026/0353824 A1
(43) Pub. Date: Nov. 5, 2026

(54) METHOD FOR MANUFACTURING A SOLID-STATE IMAGE SENSOR

(71) Applicant: SAMSUNG ELECTRONICS CO., LTD., Suwon-si (KR)

(72) Inventors: Keitada MINEO, Suwon-si (KR); Takeshi Yanagita, Suwon-si (KR)

(73) Assignee: SAMSUNG ELECTRONICS CO., LTD., Suwon-si (KR)

(21) Appl. No.: 19/538,368

(22) Filed: Feb. 12, 2026

(30) Foreign Application Priority Data
Mar. 3, 2025 (JP) 2025-032719

(51) Int. Cl. H10F 39/00; H10F 39/18

(52) U.S. Cl. CPC H10F 39/028; H10F 39/014; H10F 39/184; H10F 39/8033; H10F 39/805; H10F 39/807; H10F 39/811

(57) ABSTRACT

A method for manufacturing a solid-state image sensor including a photoelectric conversion portion is provided. The method includes: forming a sacrificial layer in a trench extending from a second substrate surface of a substrate layer having a first substrate surface and the second substrate surface opposite to the first substrate surface; forming the photoelectric conversion portion in the substrate layer from the second substrate surface; removing the sacrificial layer; and embedding a metal portion in the trench.

### CROSS-REFERENCE TO RELATED APPLICATION

This application claims priority to Japanese Patent Application No. 2025-032719, filed in the Japan Patent Office on Mar. 3, 2025, the disclosure of which is incorporated by reference herein in its entirety.

### BACKGROUND

The present disclosure relates to a method for manufacturing a solid-state image sensor.

A solid-state image sensor may include a photoelectric conversion portion (e.g., a Single Photon Avalanche Diode (SPAD)) that amplifies a charge generated by photoelectric conversion of incident light by avalanche amplification and outputs an electrical signal.

In a back-side illuminated solid-state image sensor, various optical elements (for example, on-chip lenses, etc.) are disposed on the back side of a substrate layer, a metal wiring layer is disposed on the front side opposite to the back side, and light is incident from the back side.

In the back-side illuminated solid-state image sensor, "crosstalk" may occur due to light that has passed through the substrate layer from the back side leaking to an adjacent photoelectric conversion portion (adjacent pixel) near the front surface of the substrate layer. To prevent the occurrence of crosstalk, an isolation portion (e.g., Metal Deep Trench Isolation (MDTI)) including a metal portion may be provided between adjacent photoelectric conversion portions. By forming the isolation portion to a position deeper than the front side of the substrate layer, the occurrence of crosstalk can be more reliably suppressed.

In a related backside DTI method, a trench is formed on the back side of a substrate layer for embedding a metal portion, and after forming the trench, a fixed charge film is formed to prevent the occurrence of noise and the like. After forming the fixed charge film, a protection film (insulation film) is disposed in the trench. Then, the metal portion is embedded in the trench where the protection film is disposed. Accordingly, in the backside DTI method, the embedding depth of the metal portion is limited by the position in the depth direction of the protection film formed in the substrate layer before the metal portion. Therefore, it becomes difficult to extend the isolation portion to a position deeper than the front side of the substrate layer.

In a related frontside DTI method, because a trench is formed from the front side of the substrate layer and the metal portion is embedded from the front side of the substrate layer, it becomes possible to extend the isolation portion to a position deeper than the front side of the substrate layer. However, in the related frontside DTI method, to prevent contamination caused by the metal portion, after forming the photoelectric conversion portion in the substrate layer, a trench is formed, and thereafter, the operation of embedding the metal portion in the trench is performed. Accordingly, in the related frontside DTI method, the photoelectric conversion portion is provided in the substrate layer at the stage when the trench is formed in the substrate layer. Therefore, when performing annealing for defect recovery against defects such as etching damage that occur when forming the trench in the substrate layer, the annealing temperature cannot be set high in consideration of the effect of heat on the photoelectric conversion portion, which causes deterioration of the Dark Count Rate (DCR) of the solid-state image sensor.

### SUMMARY

One or more example embodiments provide a method for manufacturing a solid-state image sensor that can effectively prevent crosstalk between adjacent pixels and at the same time achieve improve Dark Count Rate (DCR) characteristics.

According to an aspect of an example embodiment, a method for manufacturing a solid-state image sensor including a photoelectric conversion portion, includes: forming a sacrificial layer in a trench extending from a second substrate surface of a substrate layer having a first substrate surface and the second substrate surface opposite to the first substrate surface; forming the photoelectric conversion portion in the substrate layer from the second substrate surface; removing the sacrificial layer; and embedding a metal portion in the trench.

According to another aspect of an example embodiment, a method for manufacturing a solid-state image sensor including a photoelectric conversion portion, includes: forming a sacrificial layer in a trench extending from a second substrate surface of a substrate layer having a first substrate surface and the second substrate surface opposite to the first substrate surface; forming the photoelectric conversion portion in the substrate layer from the second substrate surface; removing a portion of the sacrificial layer from the second substrate surface; embedding a first metal portion in the trench; thinning the substrate layer from the first substrate surface to expose a portion of the sacrificial layer on the first substrate surface; forming a protection layer covering the sacrificial layer on the first substrate surface; forming a contact hole in the protection layer at a position corresponding to the sacrificial layer; removing the sacrificial layer remaining in the substrate layer from the first substrate surface; embedding a second metal portion in the trench from the first substrate surface a portion where the sacrificial layer was removed; and patterning the second metal portion on the first substrate surface.

According to another aspect of an example embodiment, a solid-state image sensor includes: a substrate layer having a first substrate surface, a second substrate surface opposite to the first substrate surface, and a plurality of photoelectric conversion portions; and an isolation portion between the plurality of photoelectric conversion portions, wherein the isolation portion includes: a metal portion; and a protection film on an outer side of the metal portion.

One or more example embodiments provide a method for manufacturing a solid-state image sensor that can effectively prevent crosstalk between adjacent pixels and improve DCR characteristics.

### BRIEF DESCRIPTION OF DRAWINGS

The above and other aspects will be more apparent from the following description of example embodiments taken in conjunction with the accompanying drawings, in which:

FIG. 1 is a cross-sectional view showing a solid-state image sensor according to an example embodiment.

FIG. 2 is a flowchart showing each process of a method for manufacturing a solid-state image sensor according to an example embodiment.

FIG. 3 is a schematic cross-sectional view showing a method for manufacturing a solid-state image sensor according to an example embodiment.

FIG. 4 is a schematic cross-sectional view showing the method for manufacturing a solid-state image sensor according to an example embodiment.

FIG. 5 is a schematic cross-sectional view showing the method for manufacturing a solid-state image sensor according to an example embodiment.

FIG. 6 is a schematic cross-sectional view showing the method for manufacturing a solid-state image sensor according to an example embodiment.

FIG. 7 is a schematic cross-sectional view showing the method for manufacturing a solid-state image sensor according to an example embodiment.

FIG. 8 is a schematic cross-sectional view showing the method for manufacturing a solid-state image sensor according to an example embodiment.

FIG. 9 is a schematic cross-sectional view showing the method for manufacturing a solid-state image sensor according to an example embodiment.

FIG. 10 is a schematic cross-sectional view showing the method for manufacturing a solid-state image sensor according to an example embodiment.

FIG. 11 is a schematic cross-sectional view showing the method for manufacturing a solid-state image sensor according to an example embodiment.

FIG. 12 is a schematic cross-sectional view showing the method for manufacturing a solid-state image sensor according to an example embodiment.

FIG. 13 is a schematic cross-sectional view showing the method for manufacturing a solid-state image sensor according to an example embodiment.

FIG. 14 is a schematic cross-sectional view showing the method for manufacturing a solid-state image sensor according to an example embodiment.

FIG. 15 is a flowchart showing each process of a method for manufacturing a solid-state image sensor according to an example embodiment.

FIG. 16 is a schematic cross-sectional view showing a method for manufacturing a solid-state image sensor according to an example embodiment.

FIG. 17 is a schematic cross-sectional view showing the method for manufacturing a solid-state image sensor according to an example embodiment.

FIG. 18 is a flowchart showing each process of a method for manufacturing a solid-state image sensor according to an example embodiment.

FIG. 19 is a schematic cross-sectional view showing a method for manufacturing a solid-state image sensor according to an example embodiment.

FIG. 20 is a schematic cross-sectional view showing the method for manufacturing a solid-state image sensor according to an example embodiment.

FIG. 21 is a schematic cross-sectional view showing the method for manufacturing a solid-state image sensor according to an example embodiment.

FIG. 22 is a schematic cross-sectional view showing the method for manufacturing a solid-state image sensor according to an example embodiment.

FIG. 23 is a schematic cross-sectional view showing the method for manufacturing a solid-state image sensor according to an example embodiment.

FIG. 24 is a schematic cross-sectional view showing the method for manufacturing a solid-state image sensor according to an example embodiment.

FIG. 25 is a flowchart showing each process of a method for manufacturing a solid-state image sensor according to an example embodiment.

FIG. 26 is a schematic cross-sectional view showing a method for manufacturing a solid-state image sensor according to an example embodiment.

FIG. 27 is a schematic cross-sectional view showing the method for manufacturing a solid-state image sensor according to an example embodiment.

FIG. 28 is a schematic cross-sectional view showing the method for manufacturing a solid-state image sensor according to an example embodiment.

FIG. 29 is a schematic cross-sectional view showing the method for manufacturing a solid-state image sensor according to an example embodiment.

FIG. 30 is a schematic cross-sectional view showing the method for manufacturing a solid-state image sensor according to an example embodiment.

FIG. 31 is a schematic cross-sectional view showing the method for manufacturing a solid-state image sensor according to an example embodiment.

FIG. 32 is a schematic cross-sectional view showing the method for manufacturing a solid-state image sensor according to an example embodiment.

FIG. 33 is a schematic cross-sectional view showing the method for manufacturing a solid-state image sensor according to an example embodiment.

FIG. 34 is a schematic cross-sectional view showing the method for manufacturing a solid-state image sensor according to an example embodiment.

FIG. 35 is a schematic cross-sectional view showing the method for manufacturing a solid-state image sensor according to an example embodiment.

FIG. 36 is a schematic cross-sectional view showing the method for manufacturing a solid-state image sensor according to an example embodiment.

### DETAILED DESCRIPTION

Hereinafter, example embodiment embodiments will be described with reference to the accompanying drawings. In the following drawings, the same reference numerals denote the same constituent elements, and the sizes of the respective constituent elements may be exaggerated for clarity and convenience of description in the drawings. Embodiments described below are provided as examples, and various modifications are possible from such embodiments.

Hereinafter, what is described as "upper part" or "above" may include not only what is directly on top in contact, but also what is on top without contact. Similarly, what is described as "lower part" or "below" may include not only what is directly below in contact, but also what is below without contact.

A singular expression includes a plural expression unless the context clearly indicates the singular. In addition, when a certain part "includes", "comprises", or "has" a certain constituent element, it means that it may further include other constituent elements, not excluding other constituent elements, unless there is a specific description to the contrary.

Regarding the operations constituting a method, unless the order is explicitly described or there is a description to the contrary, the operations are executed in an appropriate order. It is not necessarily limited to the described order of the operations. The use of all examples or exemplary terms is merely for describing the technical idea, and the scope is not limited by the examples or exemplary terms unless limited by the claims.

In the following description, when ordinal numbers such as "first" and "second" are used for description, they are used for convenience and do not define any order unless otherwise specified.

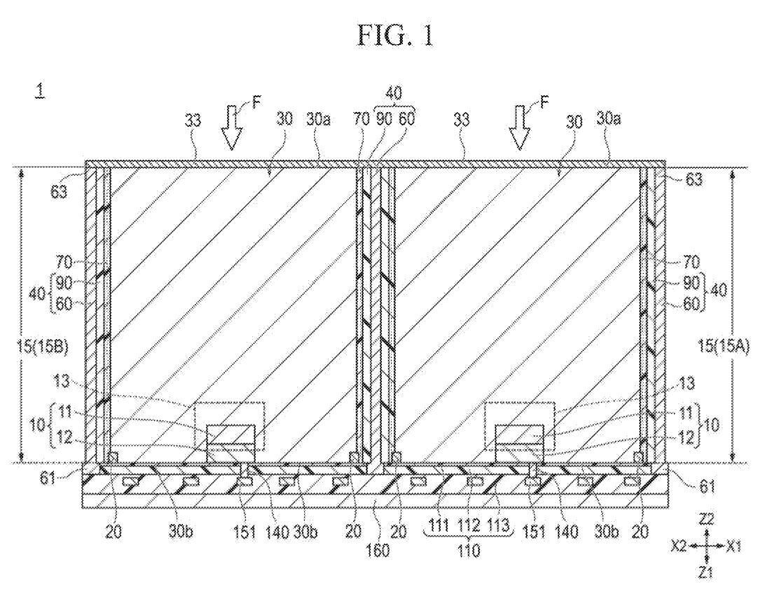

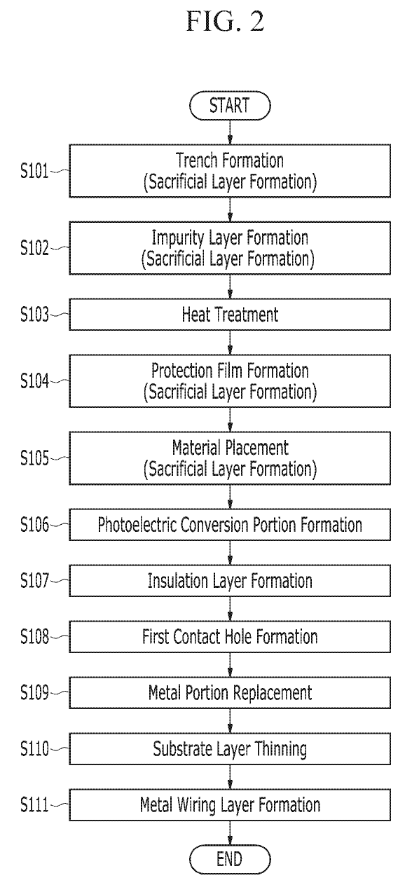

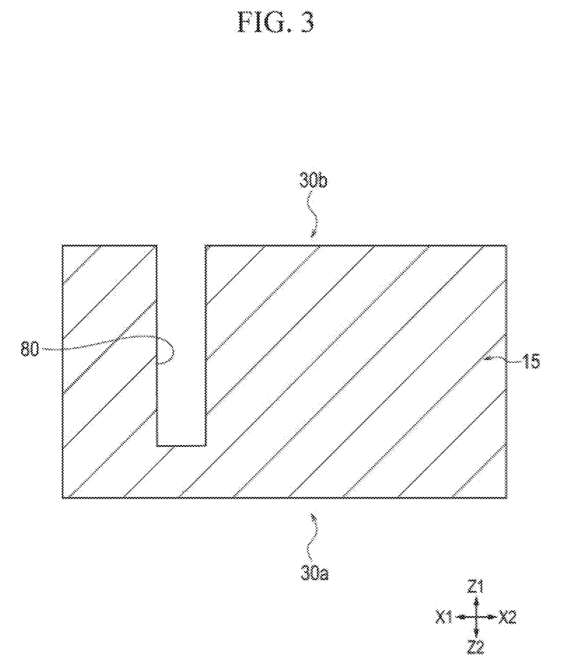

FIG. 1 is a cross-sectional view showing a structure of a solid-state image sensor 1 manufactured by a method for manufacturing a solid-state image sensor (hereinafter, also simply described as a "manufacturing method") according to an example embodiment. FIG. 2 is a flowchart showing each process of the manufacturing method according to an example embodiment. FIGS. 3 - 14 are cross-sectional views for explaining each process of the manufacturing method according to an example embodiment. And, the cross-sectional views of FIGS. 3 - 14 schematically show each process of the manufacturing method of the solid-state image sensor 1, and the scale and the like are partially changed from the cross-sectional view shown in FIG. 1, and the illustration of some structures is omitted.

As used herein, the height direction (stacking direction) of the solid-state image sensor 1 is indicated by arrows Z1-Z2 in each drawing. The "depth direction" used in the description in the specification means the direction indicated by the arrow Z1. In addition, arrows X1-X2 indicate a "width direction" orthogonal to the height direction.

### Solid-state Image Sensor 1

As shown in FIG. 1, in a solid-state image sensor 1, a substrate layer 15 (for example, 15a or 15b shown in FIG. 1) composed of a semiconductor substrate is composed of a plurality of pixels, and the plurality of pixels have a photoelectric conversion portion 30. The substrate layer 15 can be composed of, for example, a single crystal silicon substrate. In addition, a case where the pixel is a SPAD pixel is described as an example, but embodiments are not limited to a SPAD, and for example, the pixel may be implemented in sensors for near-infrared rays.

The solid-state image sensor 1 can be configured as a back-side illuminated solid-state image sensor. An arrow F shown in FIG. 1 indicates a light incident direction for the solid-state image sensor 1.

In the substrate layer 15, a surface located on a side where light is incident on the photoelectric conversion portion 30 is referred to as a "first substrate surface 30a", and a surface located on a side opposite to the first substrate surface 30a is referred to as a "second substrate surface 30b". The first substrate surface 30a corresponds to a back surface (incident surface) of the substrate layer 15, and the second substrate surface 30b corresponds to a front surface of the substrate layer 15.

In the solid-state image sensor 1, an avalanche region 13 is formed in each pixel in a predetermined direction (direction of arrow X1-X2 in FIG. 1). The avalanche region 13 causes avalanche multiplication of a charge generated in the photoelectric conversion portion 30. The photoelectric conversion portion 30 is potential-designed so that electrons generated by photoelectric conversion are gathered in the avalanche region 13.

The avalanche region 13 can be configured to have a first semiconductor layer 11 and a second semiconductor layer 12. The first semiconductor layer 11 is, for example, a P-type semiconductor layer (i.e., a semiconductor doped with P-type impurities), and the second semiconductor layer 12 is, for example, an N-type semiconductor layer (i.e., a semiconductor doped with N-type impurities). By joining the first semiconductor layer 11 and the second semiconductor layer, a PN junction 10 is formed. And, the second semiconductor layer 12 also has a function as a cathode electrode layer.

The solid-state image sensor 1 includes an isolation portion 40 to prevent the occurrence of crosstalk between adjacent photoelectric conversion portions 30 (for example, between adjacent pixels in the direction of arrow X1-X2 in FIG. 1).

The isolation portion 40 has a metal portion 60 and a protection film (insulation film) 90 disposed in contact with the metal portion 60.

The metal portion 60 extends along the height direction of the substrate layer 15. One end portion 61 (an end portion located in the direction of arrow Z1) in the length direction of the metal portion 60 is disposed at a position deeper than the second substrate surface 30b of the substrate layer 15.

The other end portion 63 (an end portion located in the direction of arrow Z2) of the metal portion 60 is disposed at substantially the same position as the first substrate surface 30a of the substrate layer 15. Thus, the metal portion 60 continuously extends through the substrate layer 15 from the first substrate surface 30a to the second substrate surface 30b.

A portion other than the one end portion 61 of the metal portion 60 extends with a substantially constant cross-sectional shape (cross-sectional area) along the height direction of the substrate layer 15. The one end portion 61 of the metal portion 60 has a cross-sectional shape that is wider or narrower in the width direction than other portions of the metal portion 60. That is, in the cross-sectional view shown in FIG. 1, the one end portion 61 of the metal portion 60 has a shape that protrudes or is narrowed in the direction of arrow X1-X2 compared to other portions of the metal portion 60.

As described above, in the solid-state image sensor 1, the metal portion 60 included in the isolation portion 40 extends to a position deeper than the second substrate surface 30b of the substrate layer 15. In addition, the one end portion 61 of the metal portion 60 has a shape that is wider or narrower in the width direction than other portions of the metal portion 60. The solid-state image sensor 1, by including the metal portion 60 of the configuration extending to a deep position as described above, can effectively prevent crosstalk from occurring on the second substrate surface 30b of the substrate layer 15.

The metal portion 60 can be composed of a metal material such as tungsten (W).

The protection film 90 can be composed of, for example, silicon dioxide (SiO₂).

The solid-state image sensor 1 has an impurity layer (semiconductor film) 70 disposed in contact with the protection film 90. The impurity layer 70 has substantially the same height as the protection film 90.

The impurity layer 70 is disposed in contact with an anode electrode layer 20 disposed on the second substrate surface 30b.

The impurity layer 70 can be configured as, for example, a P-type semiconductor layer.

The anode electrode layer 20 can be configured as, for example, a P-type semiconductor layer.

The impurity layer 70 forms an electric field for guiding electrons generated in the photoelectric conversion portion 30 to the avalanche region 13 by applying a reverse bias voltage between the anode electrode layer 20 and the second semiconductor layer 12 (cathode electrode layer).

The impurity layer 70 can be configured, for example, by implanting boron (B) into the substrate layer 15.

On the first substrate surface 30a of the substrate layer 15, an anti-reflection film 33 for preventing reflection of incident light is disposed.

On the anti-reflection film 33, a color filter and an on-chip lens corresponding to the photoelectric conversion portion 30 can be disposed. The color filter can be formed by, for example, any one of a color filter that selectively transmits light of a red (R) wavelength component, a color filter that selectively transmits light of a green (G) wavelength component, and a color filter that selectively transmits light of a blue (B) wavelength component, corresponding to the photoelectric conversion portion 30. For example, color filters disposed on adjacent photoelectric conversion portions 30 may selectively transmit light of different wavelength components.

On the second substrate surface 30b of the substrate layer 15, an insulation layer (Interlayer insulation film) 110 is disposed.

The insulation layer 110 has a first insulation layer 111 disposed in contact with the second substrate surface 30b, a second insulation layer 112 stacked on the first insulation layer 111, and a third insulation layer 113 stacked on the second insulation layer 112.

The first insulation layer 111 can be composed of, for example, silicon nitride (SiN). The second insulation layer 112 and the third insulation layer 113 can be composed of, for example, silicon dioxide (SiO₂).

A metal wiring layer 151 is disposed on the second insulation layer 112. The metal wiring layer 151 is connected to the photoelectric conversion portion 30 through a metal conductive portion 140.

The conductive portion 140 and the metal wiring layer 151 can be composed of a metal material such as copper (Cu).

A bottom substrate layer 160 covering the third insulation layer 113 is disposed below the third insulation layer 113 in the depth direction.

The bottom substrate layer 160 can be composed of, for example, a single crystal silicon substrate.

### Method For Manufacturing Solid-State Image Sensor 1

Hereinafter, a manufacturing method according to an example embodiment will be described with reference to the flowchart shown in FIG. 2 and the cross-sectional views shown in FIGS. 3 - 14.

Referring to FIG. 2, the manufacturing method according to an example embodiment will be outlined.

The manufacturing method according to an example embodiment has a sacrificial layer formation operation of forming a sacrificial layer 50 from a second substrate surface 30b of a substrate layer 15 having a first substrate surface 30a and the second substrate surface 30b located on a side opposite to the first substrate surface 30a, a photoelectric conversion portion formation operation S106 of forming a photoelectric conversion portion 30 in the substrate layer 15 from the second substrate surface 30b located on a side opposite to the first substrate surface 30a where light is incident on the photoelectric conversion portion 30, and a metal portion replacement operation S109 of removing the sacrificial layer 50 from the substrate layer 15 and replacing the sacrificial layer 50 with a metal portion 60 by embedding a metal in a portion where the sacrificial layer 50 was removed.

The method for manufacturing the solid-state image sensor 1 according to an example embodiment may arbitrarily and additionally include the following respective processes.

The manufacturing method according to an example embodiment further has a heat treatment operation S103 performed before the photoelectric conversion portion formation operation S106.

In the manufacturing method according to an example embodiment, the sacrificial layer formation operation has a trench formation operation S101 of forming a trench 80 in the substrate layer 15 from the second substrate surface 30b, an impurity layer formation operation S102 of forming an impurity layer 70 on at least a sidewall of the trench 80 from the second substrate surface 30b, a protection film formation operation S104 of forming a protection film 90 on the impurity layer 70 formed in the trench 80, and a material placement operation S105 of disposing a material for forming the sacrificial layer 50 in an inner peripheral portion of the protection film 90, and the heat treatment operation S103 is performed after the impurity layer formation operation S102 and before the photoelectric conversion portion formation operation S106.

And, in the flowchart shown in FIG. 2, the sacrificial layer formation operation is described together with each process (S101, S102, S104, S105) included in the sacrificial layer formation operation.

The manufacturing method according to an example embodiment further has an insulation layer formation operation S107 of forming an insulation layer 110 on the second substrate surface 30b after the photoelectric conversion portion formation operation S106, and a first contact hole formation operation S108 of forming a contact hole 120 connected to the sacrificial layer 50 in the insulation layer 110 from the second substrate surface 30b after the insulation layer formation operation S107, and in the metal portion replacement operation S109, while replacing the sacrificial layer 50 with the metal portion 60, the metal portion 60 is extended into the contact hole 120.

In addition, the manufacturing method according to an example embodiment has a substrate layer thinning operation S110 of thinning the substrate layer 15 from the first substrate surface 30a after the metal portion replacement operation S109, and a metal wiring layer formation operation S111 of forming a metal wiring layer 151 on the insulation layer 110.

Referring to FIGS. 3 - 14, each process will be described.

Hereinafter, a method of manufacturing a back-side illuminated solid-state image sensor by a so-called "frontside DTI method" of forming an isolation portion 40 from the second substrate surface 30b (front side) of the substrate layer 15 will be described.

As shown in FIG. 3, a substrate layer 15 is prepared, and a trench 80 is formed in the substrate layer 15 from the second substrate surface 30b (trench formation operation S101).

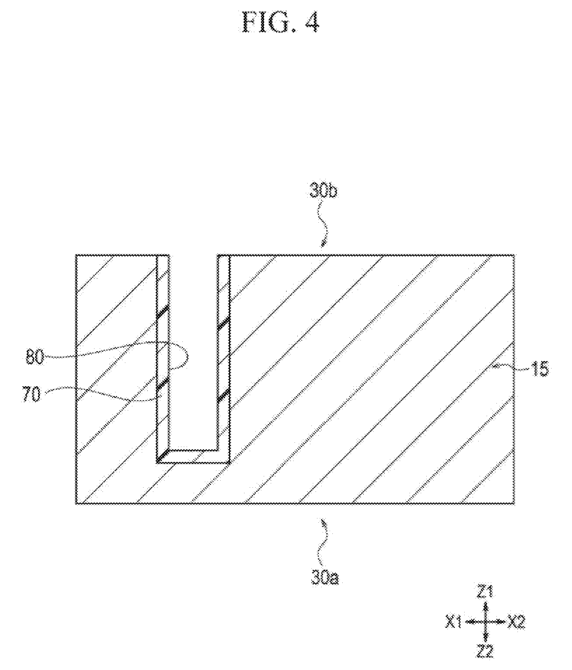

As shown in FIG. 4, an impurity (for example, boron) is implanted into the substrate layer 15 from the second substrate surface 30b, and an impurity layer 70 is formed on at least a sidewall of the trench 80 (impurity layer formation operation S102).

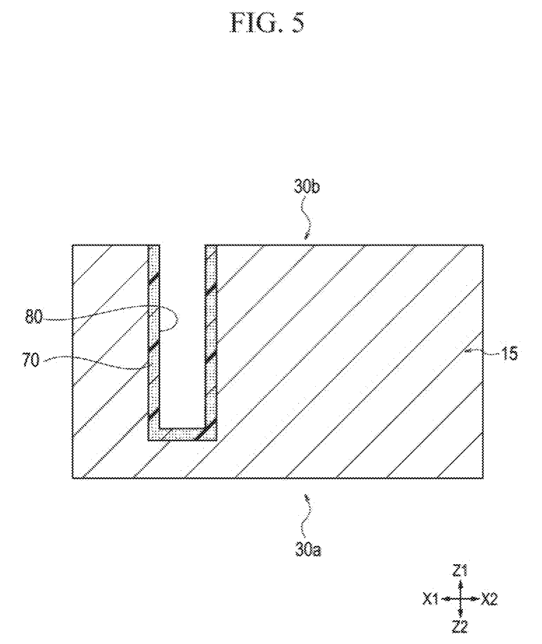

As shown in FIG. 5, a heat treatment (annealing treatment) is performed on the impurity layer 70 (heat treatment operation S103).

According to an example embodiment, because the heat treatment is performed on the impurity layer 70 before forming the photoelectric conversion portion 30 in the substrate layer 15, the effect of heat during the heat treatment does not reach the photoelectric conversion portion 30. For this reason, the heat treatment may be performed on the impurity layer 70 at a higher temperature. Thereby, it is possible to achieve recovery of defects due to impurity implantation and effective improvement of the impurity profile. In FIG. 5 and subsequent figures, dots are shown in the impurity layer 70 on which the heat treatment has been performed.

And, the timing of performing the heat treatment operation S103 is not limited, as long as it is after the impurity layer 70 is formed and before the photoelectric conversion portion 30 is formed. For example, the heat treatment operation S103 may be performed immediately after a protection film formation operation S104 or a material placement operation S105 to be described later.

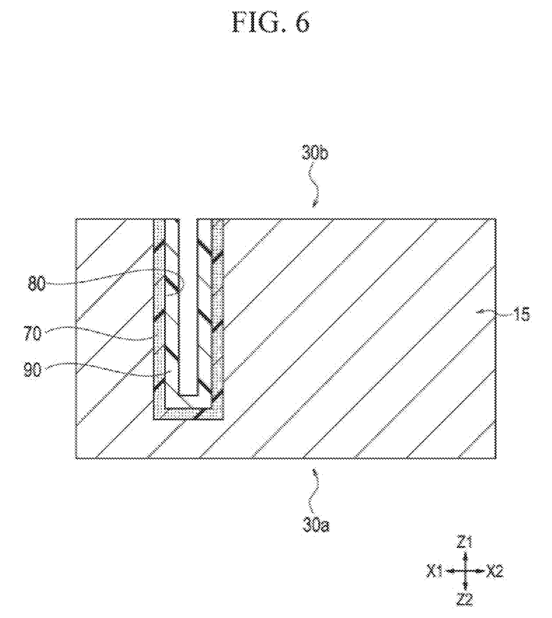

As shown in FIG. 6, a protection film 90 is formed on the impurity layer 70 formed on the sidewall of the trench 80 (protection film formation operation S104).

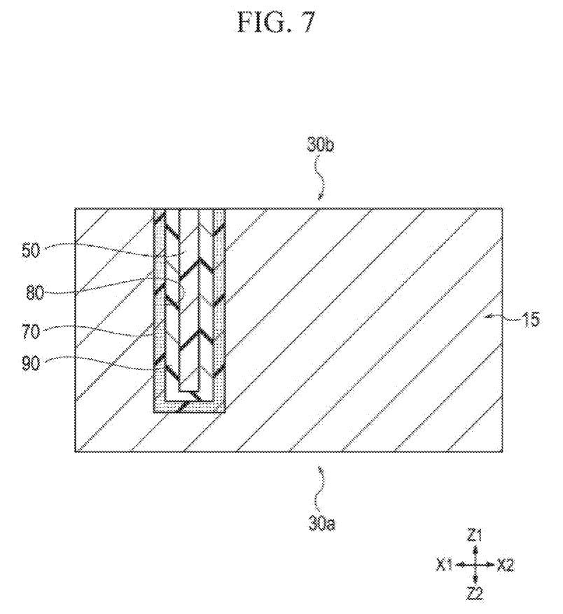

As shown in FIG. 7, a material for forming a sacrificial layer 50 is disposed in an inner peripheral portion of the protection film 90 formed in the trench 80 (material placement operation S105). The sacrificial layer 50 can be formed to fill the entire inner peripheral side region of the protection film 90. The sacrificial layer 50 can be composed of, for example, polycrystalline silicon (Poly-Si).

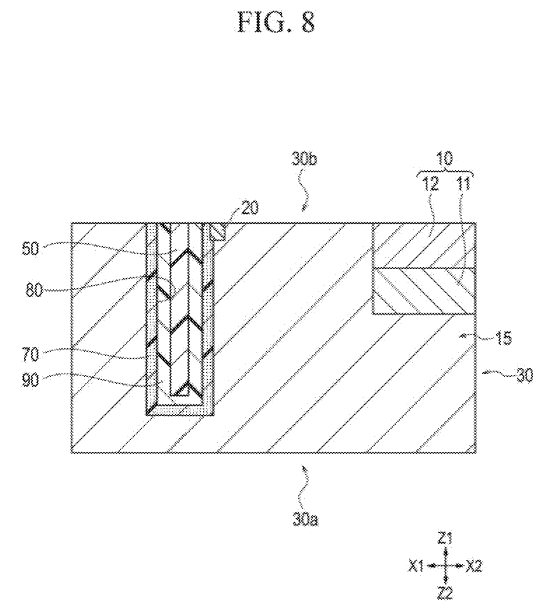

As shown in FIG. 8, a photoelectric conversion portion 30 is formed by ion implantation or the like from the second substrate surface 30b (photoelectric conversion portion formation operation S106). After the formation of the photoelectric conversion portion 30, a PN junction 10 including a second semiconductor layer 12 (cathode electrode layer) and an anode electrode layer 20 are formed. While forming the photoelectric conversion portion 30, the sacrificial layer 50, not the metal portion 60, is provided in the trench 80. For this reason, it is possible to prevent metal contamination from occurring in the photoelectric conversion portion 30.

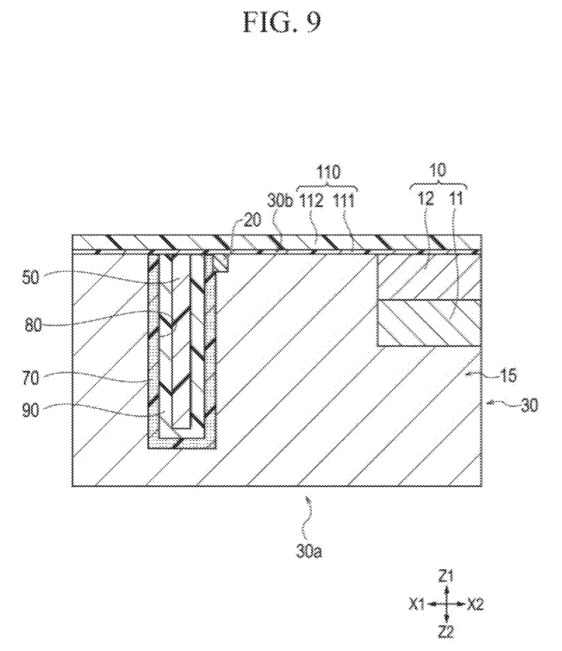

As shown in FIG. 9, an insulation layer 110 is formed on the second substrate surface 30b (insulation layer formation operation S107). The insulation layer 110 may include a first insulation layer 111 (SiN layer) for defining an etching depth when forming a contact hole 120 to be described later, and a second insulation layer 112 (SiO₂ layer) stacked on the first insulation layer 111.

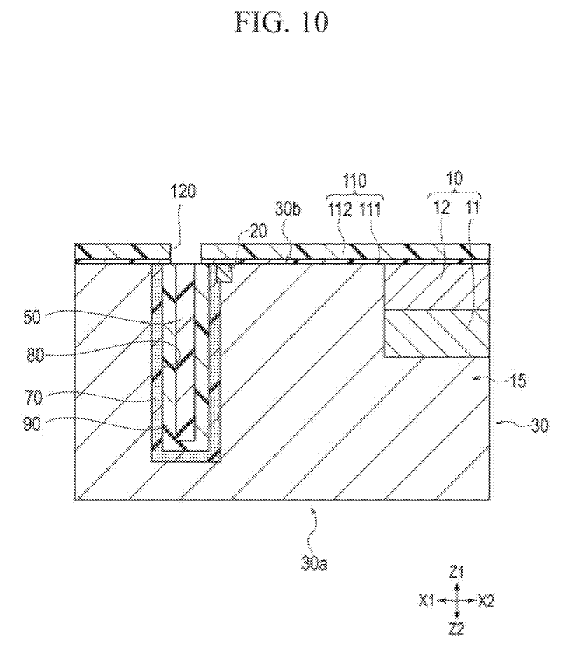

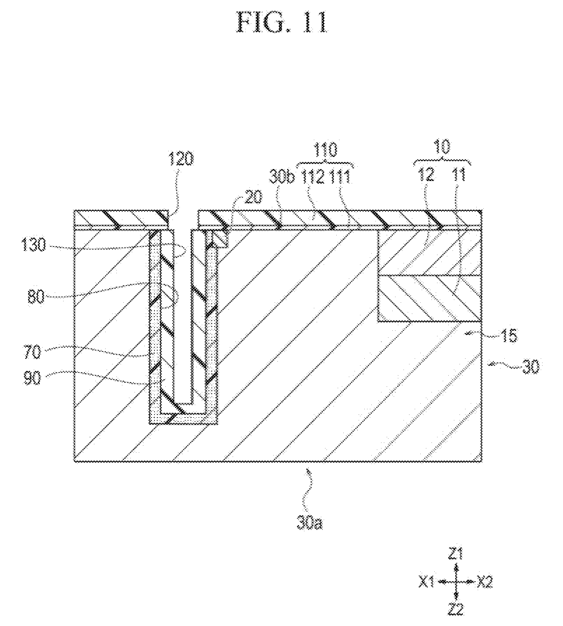

As shown in FIG. 10, a contact hole 120 connected to the sacrificial layer 50 is formed in the insulation layer 110 from the second substrate surface 30b (first contact hole formation operation S108). The width of the contact hole 120 may be larger than the width of a trench 130 (see FIG. 11) formed after removing the sacrificial layer 50. Thereby, when removing the sacrificial layer 50, it becomes easy to perform processing on the sacrificial layer 50 through the contact hole 120 from the second substrate surface 30b. However, example embodiments are not limited thereto and, for example, the width of the contact hole 120 may be smaller than the width of the trench 130.

The formation of the contact hole 120 can be performed, for example, by wet etching. And, when forming the contact hole 120, a mask of a predetermined pattern covering the second insulation layer 112 can be used.

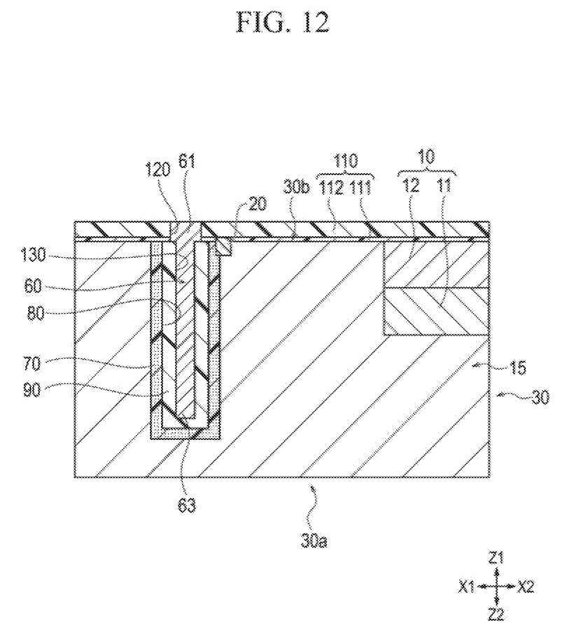

As shown in FIGS. 11 and 12, the sacrificial layer 50 is removed from the substrate layer 15, and a metal (for example, tungsten) is embedded in the portion where the sacrificial layer 50 was removed (trench 130), thereby replacing the sacrificial layer 50 with a metal portion 60 (metal portion replacement operation S109).

The removal of the sacrificial layer 50 from the substrate layer 15 can be performed, for example, by wet etching. By adopting wet etching, damage to the substrate layer 15 can be reduced compared to the case of adopting dry etching.

As shown in FIG. 12, in the metal portion replacement operation S109, while replacing the sacrificial layer 50 with the metal portion 60, the metal portion 60 is extended into the contact hole 120. As described above, the contact hole 120 is formed to be wider than the trench 130. For this reason, the one end portion 61 of the metal portion 60 disposed in the contact hole 120 is formed to have a larger width or a smaller width than other portions of the metal portion 60.

The metal portion 60 replaced from the sacrificial layer 50 has one end portion 61 provided in the contact hole 120 formed at a position deeper than the second substrate surface 30b of the substrate layer 15 (position on the arrow Z1 side). For example, the metal portion 60 may extend from the trench 130, past the second substrate surface 30b, into the contact hole 120. Thereby, the isolation portion 40 is formed in a shape extending to a position deeper than the second substrate surface 30b (front side) of the substrate layer 15. For this reason, the solid-state image sensor 1 can effectively prevent the occurrence of crosstalk to adjacent pixels by the isolation portion 40.

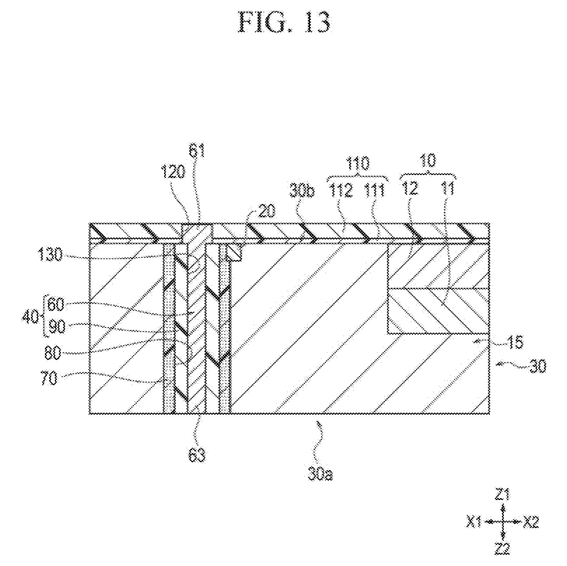

As shown in FIG. 13, the substrate layer 15 is thinned from the first substrate surface 30a (substrate layer thinning operation S110). In this process, the substrate layer 15 is polished, for example, to a position where the other end portion 63 of the metal portion 60 is exposed from the substrate layer 15.

After the above-described process is completed, an anti-reflection film 33 is formed on the first substrate surface 30a (see FIG. 1).

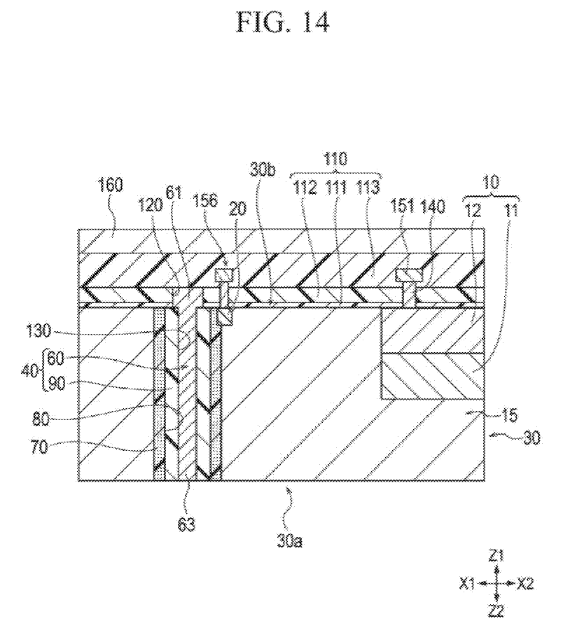

As shown in FIG. 14, a metal wiring layer 151 is formed on the insulation layer 110 (metal wiring layer formation operation S111). In forming the metal wiring layer 151, a third insulation layer 113 (SiO₂ layer) is disposed to cover the second insulation layer 112. The metal wiring layer 151 can be disposed, for example, in the third insulation layer 113. In addition, the metal wiring layer 151 disposed in the third insulation layer 113 can be connected to the second semiconductor layer 12 (cathode electrode layer) through the conductive portion 140. In addition, in the metal wiring layer formation operation S111, a wiring layer 156 connected to the anode electrode layer 20 is formed.

After forming the metal wiring layer 151, a bottom substrate layer 160 is disposed to cover the third insulation layer 113.

As described above, the method for manufacturing a solid-state image sensor 1 according to an example embodiment has a sacrificial layer formation operation of forming a sacrificial layer 50 from a second substrate surface 30b of a substrate layer 15 having a first substrate surface 30a and the second substrate surface 30b located on a side opposite to the first substrate surface 30a, a photoelectric conversion portion formation operation S106 of forming a photoelectric conversion portion 30 in the substrate layer 15 from the second substrate surface 30b located on a side opposite to the first substrate surface 30a where light is incident on the photoelectric conversion portion 30, and a metal portion replacement operation S109 of removing the sacrificial layer 50 from the substrate layer 15 and replacing the sacrificial layer 50 with a metal portion 60 by embedding a metal in a portion where the sacrificial layer 50 was removed.

According to the manufacturing method described above, the isolation portion 40 can be formed by embedding the metal portion 60 from the second substrate surface 30b of the substrate layer 15 by the frontside DTI method. For this reason, it becomes possible to extend the metal portion 60 of the isolation portion 40 to a position deeper than the second substrate surface 30b of the substrate layer 15. Thereby, it is possible to provide a solid-state image sensor 1 that can effectively prevent the occurrence of crosstalk between adjacent pixels. In addition, according to the manufacturing method described above, the sacrificial layer 50 is replaced with the metal portion 60 after forming the photoelectric conversion portion 30. For this reason, it becomes possible to perform the heat treatment for the impurity layer 70 formed around the metal portion 60 before forming the photoelectric conversion portion 30 and before embedding the metal portion 60. Thereby, it is possible to perform the heat treatment on the impurity layer 70 at a higher temperature before the photoelectric conversion portion 30 is formed, and it becomes possible to effectively improve the recovery of defects due to impurity implantation and the profile of impurities. Therefore, it becomes possible to provide a solid-state image sensor 1 with improved DCR characteristics.

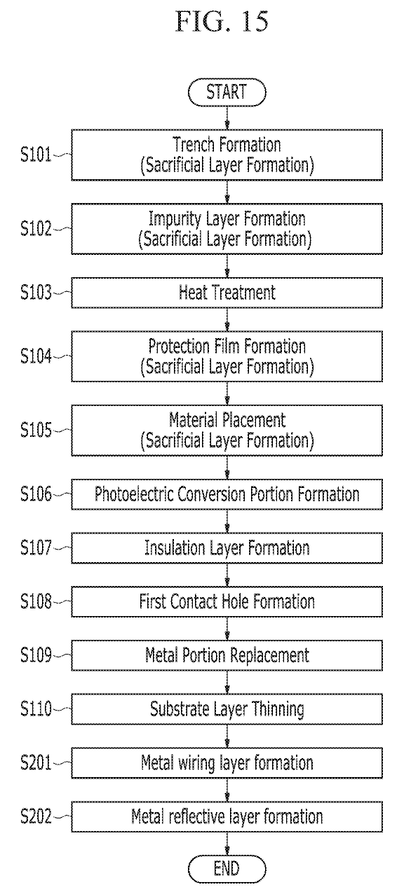

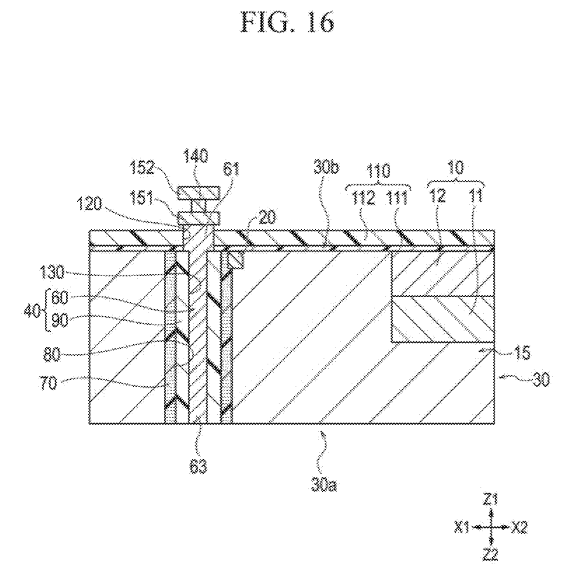

Next, a method for manufacturing a solid-state image sensor 1 according to an example embodiment will be described with reference to the flowchart shown in FIG. 15 and the cross-sectional views shown in FIGS. 16 - 17. For example, the method may correspond to a first modification (i.e., Modification 1) of the above-described example.

The flowchart shown in FIG. 15 shows each process of the manufacturing method according to Modification 1.

In the flowchart shown in FIG. 15, the same process numbers are given to those having the same order and work content as each process shown in the flowchart shown in FIG. 2.

In the manufacturing method according to Modification 1, the trench formation operation S101 to the substrate layer thinning operation S110 are the same as discussed above, and the metal wiring layer formation operation S201 and the metal reflective layer formation operation S202 have different orders and/or work contents. In the following description, the description of the trench formation operation S101 to the substrate layer thinning operation S110 will be omitted.

In the manufacturing method according to Modification 1, after performing the metal portion replacement operation S109, the substrate layer thinning operation S110 is performed. An operator, after performing these respective processes, performs a metal wiring layer formation operation S201 of forming a metal wiring layer 151 on the insulation layer 110.

FIG. 16 shows a state when the metal wiring layer formation operation S201 is performed.

As shown in FIG. 16, in the metal wiring layer formation operation S201 according to Modification 1, the metal wiring layer 151 is stacked on the one end portion 61 of the metal portion 60 located on the second substrate surface 30b. By stacking the metal wiring layer 151 on the one end portion 61 of the metal portion 60 in this way, the metal wiring layer 151 can be disposed at a deeper position in the solid-state image sensor 1. For this reason, the solid-state image sensor 1 has a structure in which the metal portion 60 of the isolation portion 40 and the metal wiring layer 151 are continuously connected in the height direction. Thereby, the solid-state image sensor 1 can block the movement (leakage) of light between adjacent pixels at a deeper position of the solid-state image sensor 1. For this reason, the occurrence of crosstalk can be even more effectively prevented.

And, as shown in FIG. 16, a metal wiring layer 152 may be disposed at a deeper position than the metal wiring layer 151, and the metal wiring layer 151 and the metal wiring layer 152 may be connected by the conductive portion 140. By adopting such a configuration, the occurrence of crosstalk can be more effectively prevented.

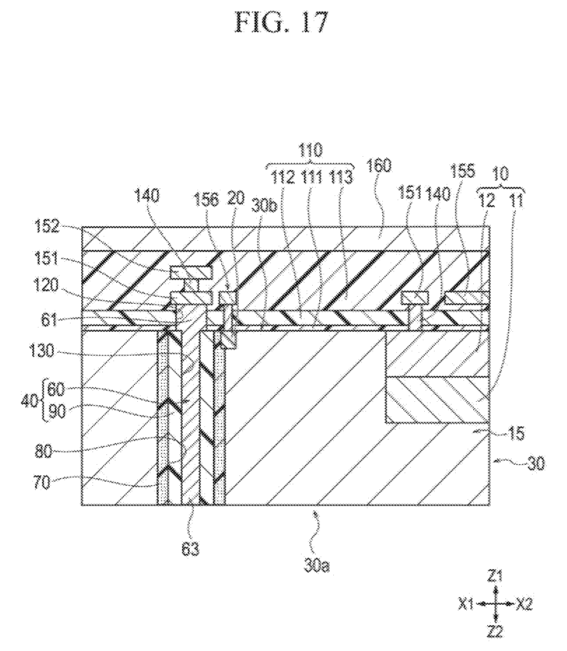

As shown in FIG. 17, the metal wiring layer formation operation S201 according to Modification 1 further has a metal reflective layer formation operation S202 of forming a metal reflection layer 155 on the insulation layer 110 (for example, the third insulation layer 113) at a position corresponding to the photoelectric conversion portion 30.

In the method for manufacturing a solid-state image sensor 1 according to Modification 1, by forming the metal reflection layer 155, it becomes possible to reflect light leaking from the photoelectric conversion portion 30 to the second substrate surface 30b to the first substrate surface 30a. For this reason, the occurrence of crosstalk can be more effectively prevented. And, the "insulation layer 110 at a position corresponding to the photoelectric conversion portion 30" described above indicates a range (region) of the insulation layer disposed at a position overlapping with the photoelectric conversion portion 30 on the arrow Z1 direction side in the cross-sectional view shown in FIG. 17.

The metal reflection layer 155 can be formed, for example, at the same stacking position as the metal wiring layer 151 (the same position in the height direction in the third insulation layer 113), substantially simultaneously with the metal wiring layer 151 in the same process. Thereby, because it becomes possible to form the metal reflection layer 155 in the same process when forming the metal wiring layer 151, it becomes possible to simplify the manufacturing work.

The metal reflection layer 155 can be composed of a metal material such as copper (Cu).

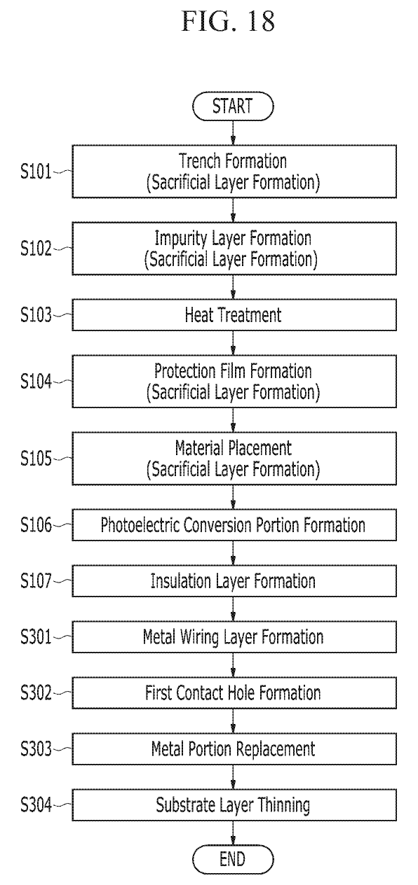

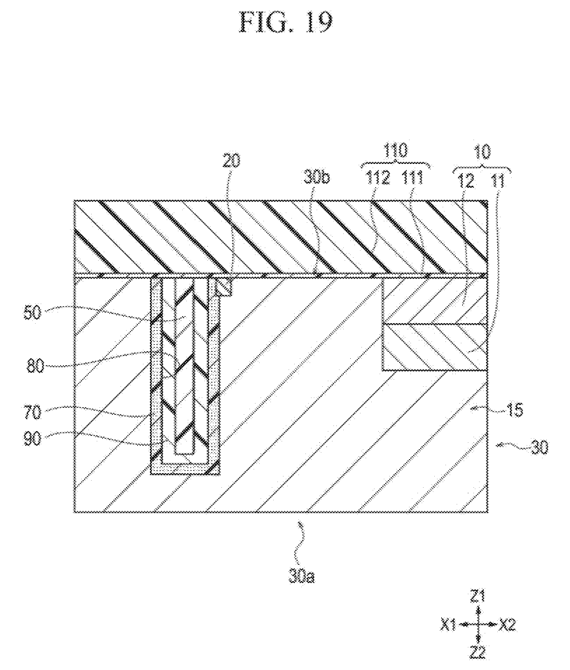

Next, a manufacturing method according to an example embodiment will be described with reference to the flowchart shown in FIG. 18 and the cross-sectional views shown in FIGS. 19 - 24. For example, the method may correspond to a second modification (i.e., Modification 2).

The flowchart shown in FIG. 18 shows each process of the manufacturing method according to Modification 2.

In the flowchart shown in FIG. 18, the same process numbers are given to those having the same order and work content as each process shown in the flowchart shown in FIG. 2.

In the manufacturing method according to Modification 2, the trench formation operation S101 to the insulation layer formation operation S107 are the same as discussed above, and the metal wiring layer formation operation S301 to the substrate thinning operation S304 have different orders and/or work contents. In the following description, the description of the trench formation operation S101 to the insulation layer formation operation S107 will be omitted.

As discussed above, after performing the insulation layer formation operation S107, the work may then proceed in the order of the first contact hole formation operation S108, the metal portion replacement operation S109, the substrate layer thinning operation S110, and the metal wiring layer formation operation S111 (see FIG. 2). However, example embodiments are not limited thereto. For example, as shown in FIG. 18, in Modification 2, after performing the insulation layer formation operation S107, the work proceeds in the order of the metal wiring layer formation operation S301, the first contact hole formation operation S302, the metal portion replacement operation S303, and the substrate layer thinning operation S304.

FIG. 19 shows a state after the insulation layer formation operation S107 has been performed.

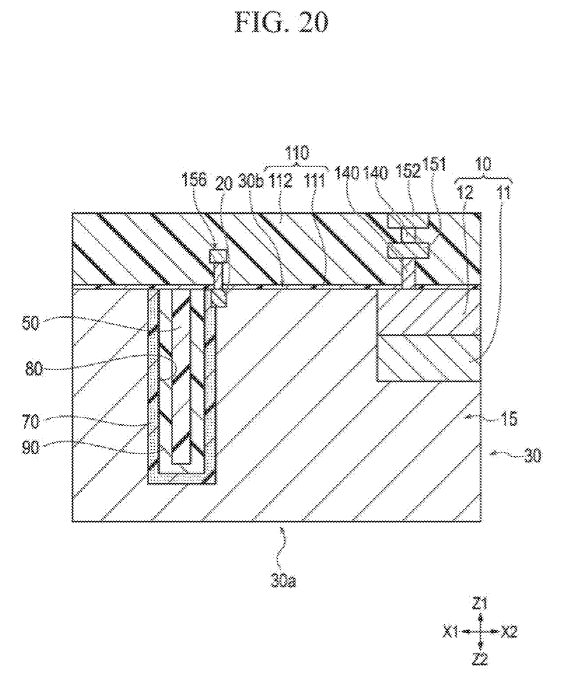

As shown in FIG. 20, after performing the insulation layer formation operation S107, a metal wiring layer formation operation S301 is performed.

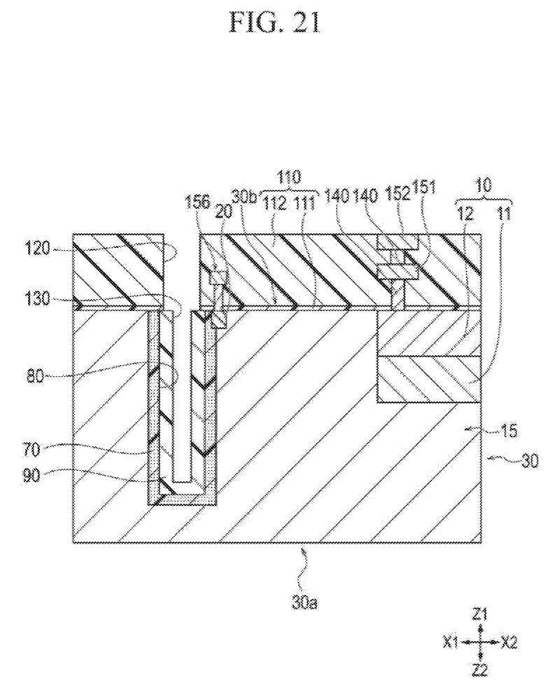

As shown in FIG. 21, after performing the metal wiring layer formation operation S301, a first contact hole formation operation S302 is performed to remove the sacrificial layer 50.

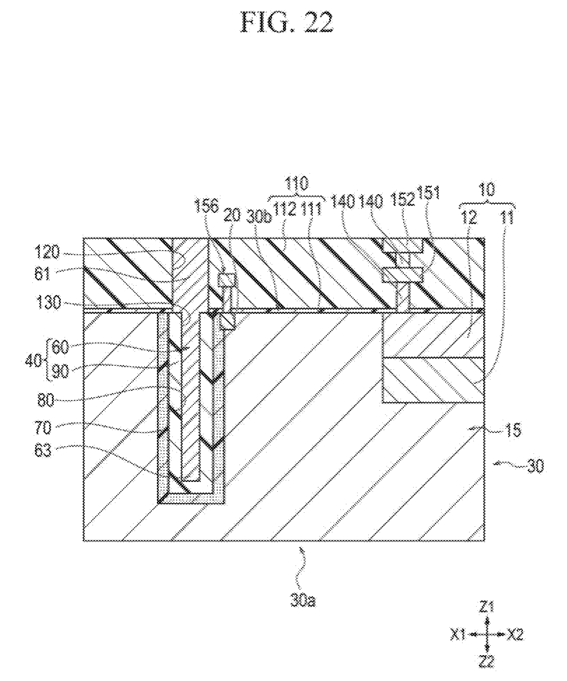

As shown in FIG. 22, after performing the first contact hole formation operation S302, a metal portion replacement operation S303 is performed to form the metal portion 60. At this time, while replacing the sacrificial layer 50 with the metal portion 60, the metal portion 60 is extended into the contact hole 120.

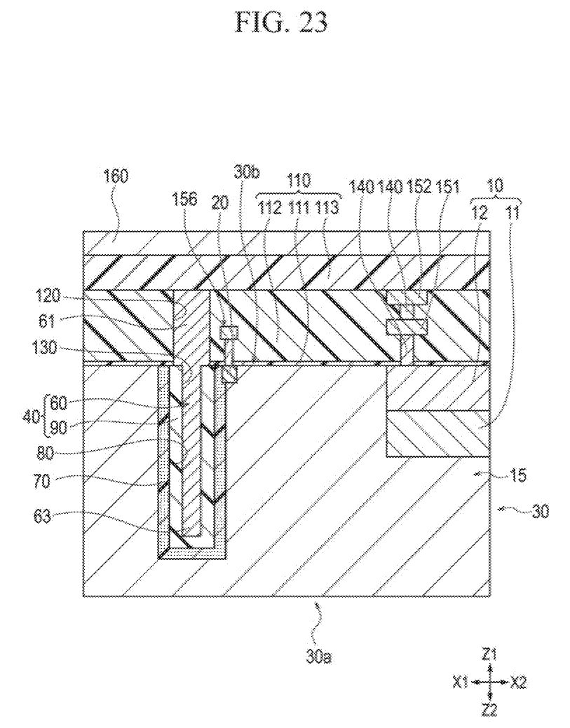

As shown in FIG. 23, after performing the metal portion replacement operation S303, a third insulation layer 113 and a bottom substrate layer 160 are disposed.

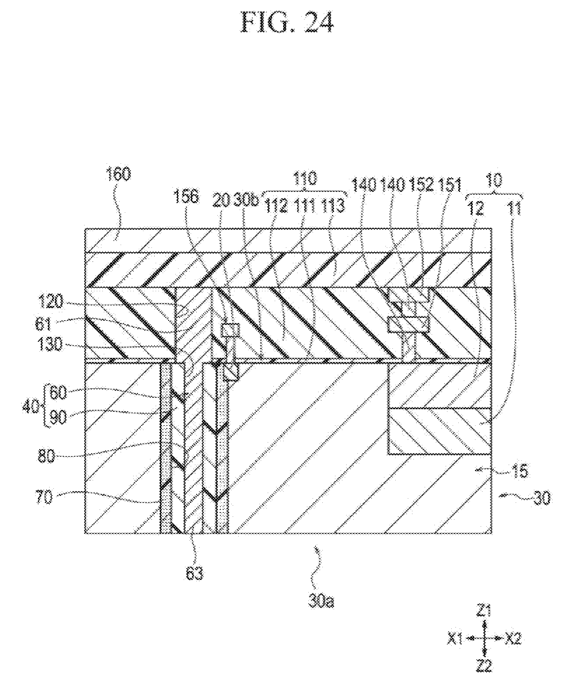

As shown in FIG. 24, after performing the metal portion replacement operation S303, a substrate layer thinning operation S304 is performed.

As described above, when forming the isolation portion 40 to a deeper position by the frontside DTI method, the metal portion replacement operation S303 may be performed after performing the metal wiring layer formation operation S301. That is, the front-back relationship of the order of performing the metal wiring layer formation operation and the metal portion replacement operation can be arbitrarily changed.

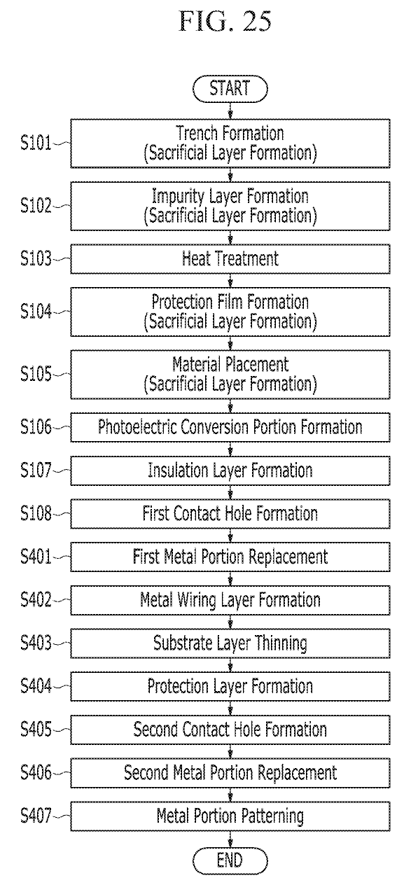

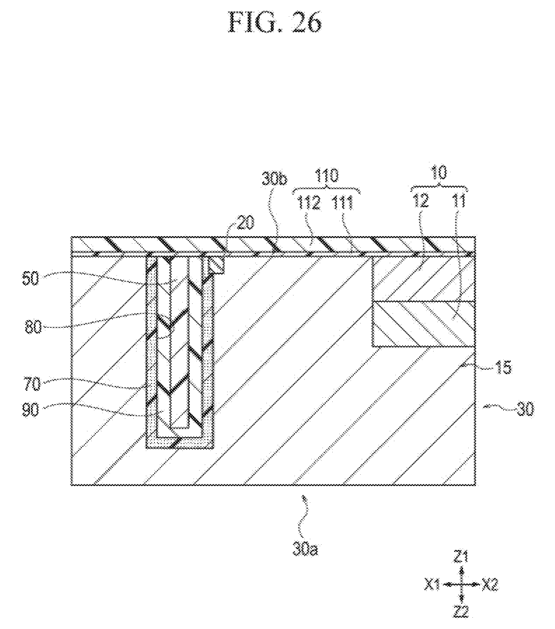

Next, a manufacturing method according to an example embodiment will be described with reference to the flowchart shown in FIG. 25 and the cross-sectional views shown in FIGS. 26 - 36.

The flowchart shown in FIG. 25 shows each process of the manufacturing method according to an example embodiment.

In the flowchart shown in FIG. 25, the same process numbers are given to those having the same order and work content as each process shown in the flowchart shown in FIG. 2.

Referring to FIG. 25, the manufacturing method of the solid-state image sensor 1 according to an example embodiment will be schematically described.

The manufacturing method of the solid-state image sensor 1 according to an example embodiment has a sacrificial layer formation operation of forming a sacrificial layer 50 from a second substrate surface 30b of a substrate layer 15 having a first substrate surface 30a and the second substrate surface 30b located on a side opposite to the first substrate surface 30a, a photoelectric conversion portion formation operation S106 of forming a photoelectric conversion portion 30 in the substrate layer 15 from the second substrate surface 30b located on a side opposite to the first substrate surface 30a where light is incident on the photoelectric conversion portion 30, a first metal portion replacement operation S401 of removing a portion of the sacrificial layer 50 from the second substrate surface 30b and replacing the portion of the sacrificial layer 50 with a metal portion 60 by embedding a metal in a portion where the sacrificial layer 50 was removed, a substrate layer thinning operation S403 of thinning the substrate layer 15 from the first substrate surface 30a to expose a portion of the sacrificial layer 50 on the first substrate surface 30a, a protection layer formation operation S404 of forming a protection layer 170 covering the sacrificial layer 50 on the first substrate surface 30a, a second contact hole formation operation S405 of forming a contact hole 180 in the protection layer 170 at a position corresponding to the sacrificial layer 50, a second metal portion replacement operation S406 of removing the sacrificial layer 50 remaining in the substrate layer 15 from the first substrate surface 30a and replacing the sacrificial layer 50 with a metal portion 200 by embedding a metal in a portion where the sacrificial layer 50 was removed, and a metal portion patterning operation S407 of patterning the metal portion 200 on the first substrate surface 30a.

In the manufacturing method of the solid-state image sensor 1 according to an example embodiment, the trench formation operation S101 to the first contact hole formation operation S108 are the same as discussed above, and the first metal portion replacement operation S401 to the metal portion patterning operation S407 have different orders and/or work contents. In the following description, the description of the trench formation operation S101 to the photoelectric conversion portion formation operation S106 will be omitted.

FIG. 26 shows a state after the insulation layer formation operation S107 has been performed.

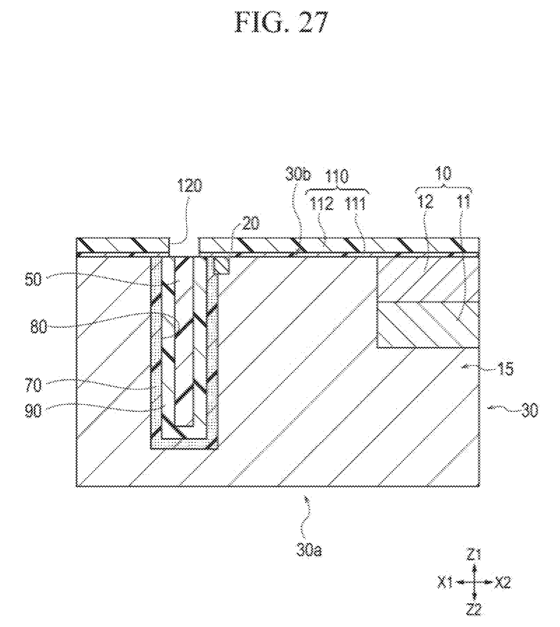

As shown in FIG. 27, after performing the insulation layer formation operation S107, a contact hole 120 is formed in the insulation layer 110 (the first insulation layer 111, the second insulation layer 112) (first contact hole formation operation S108).

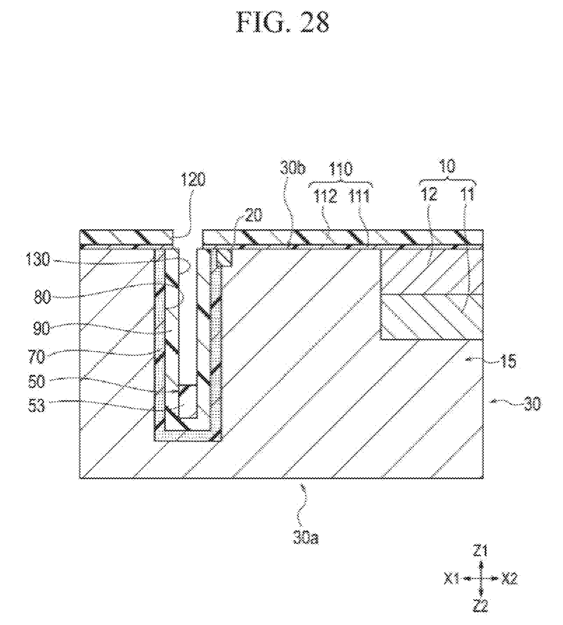

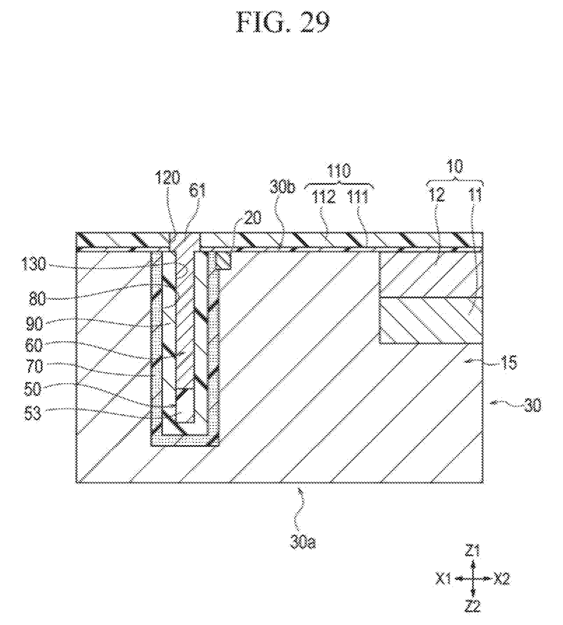

As shown in FIGS. 28 and 29, a portion of the sacrificial layer 50 is removed from the second substrate surface 30b, and a portion of the sacrificial layer 50 is replaced with a metal portion 60 by embedding a metal in the portion where the sacrificial layer 50 was removed (first metal portion replacement operation S401).

As shown in FIG. 28, in the first metal portion replacement operation S401, a portion of the sacrificial layer 50 near the other end portion 53 located on the first substrate surface 30a is left (for example, a length of about 1μm in the height direction is left). In addition, as shown in FIG. 29, in the first metal portion replacement operation S401, the metal portion 60 is extended into the contact hole 120 formed in the insulation layer 110. Thereby, the one end portion 61 of the metal portion 60 can be formed in a shape widened in the width direction.

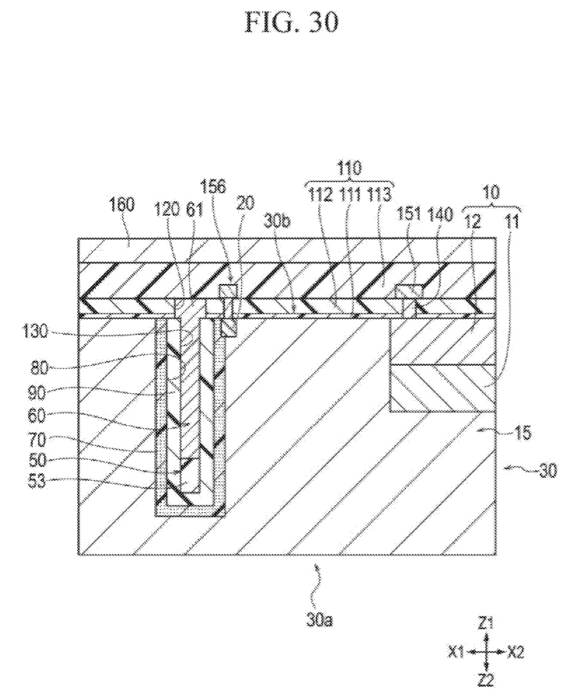

As shown in FIG. 30, a metal wiring layer 151 is formed (metal wiring layer formation operation S402). In addition, a third insulation layer 113 and a bottom substrate layer 160 are stacked on the second substrate surface 30b.

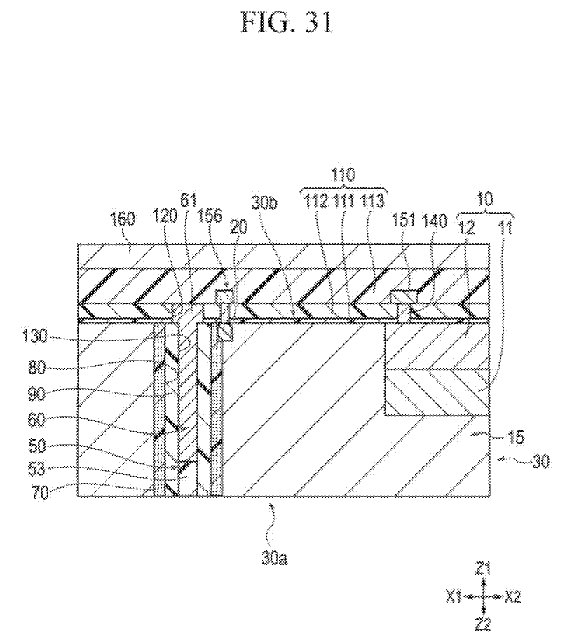

As shown in FIG. 31, the substrate layer 15 is thinned from the first substrate surface 30a to expose a portion of the sacrificial layer 50 on the first substrate surface 30a (substrate layer thinning operation S403). At this time, the end of the metal portion 60 located on the first substrate surface 30a is covered by the sacrificial layer 50. For this reason, when the substrate layer 15 is thinned from the first substrate surface 30a, it is possible to prevent the metal portion 60 from being exposed to the outside of the substrate layer 15. Thereby, it is possible to prevent the occurrence of white spots due to metal contamination or damage by the metal portion 60.

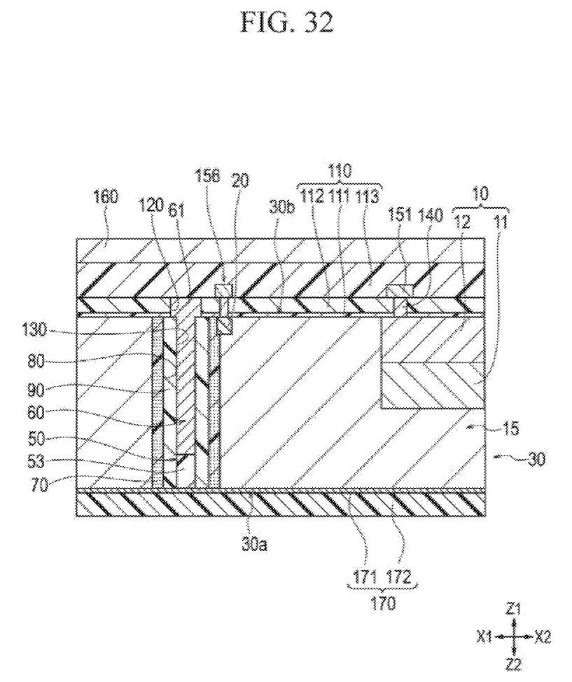

As shown in FIG. 32, a protection layer 170 covering the sacrificial layer 50 (the other end portion 53 of the sacrificial layer 50) is formed on the first substrate surface 30a (protection layer formation operation S404). The protection layer 170 may include a first protection layer 171 covering the first substrate surface 30a and a second protection layer 172 covering the first protection layer 171.

The first protection layer 171 can be composed of a high-k material such as hafnium silicate (HfSiO), hafnium oxide (HfO₂), or zirconium oxide (ZrO₂). The second protection layer 172 can be composed of, for example, silicon dioxide (SiO₂).

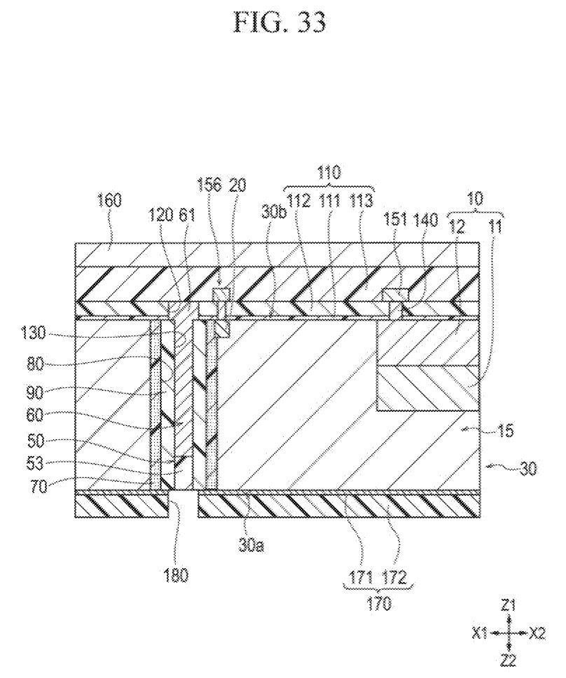

As shown in FIG. 33, a contact hole 180 is formed in the protection layer 170 at a position corresponding to the sacrificial layer 50 (second contact hole formation operation S405).

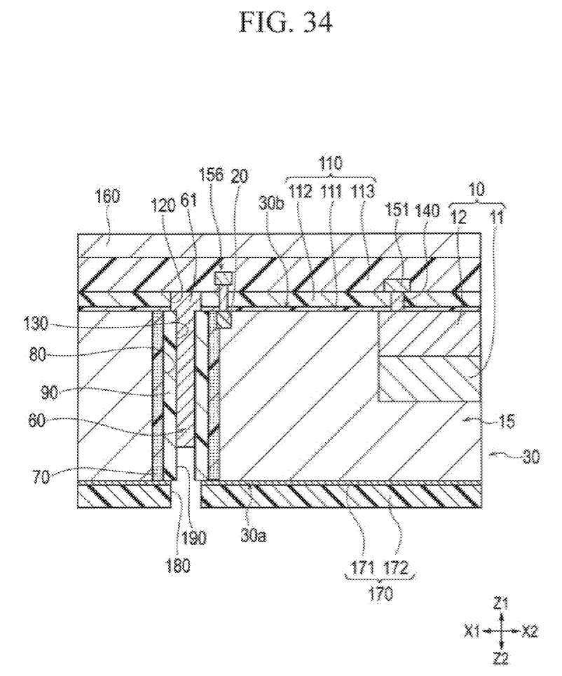

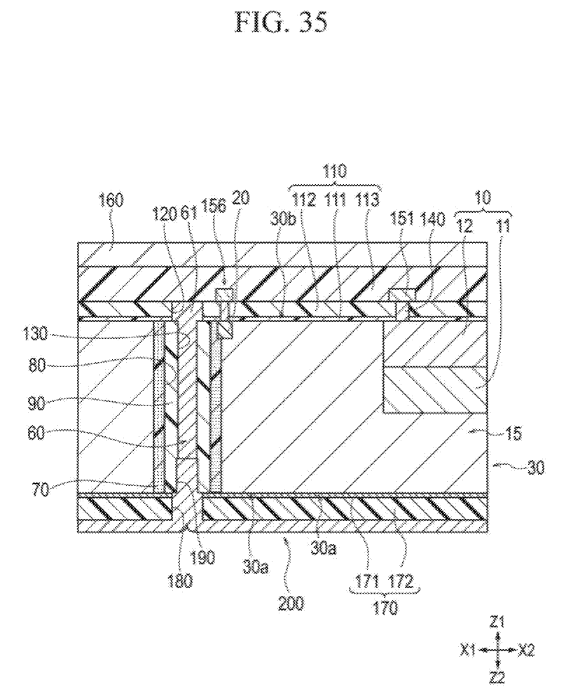

As shown in FIGS. 34 and 35, the sacrificial layer 50 remaining in the substrate layer 15 is removed from the first substrate surface 30a, and the sacrificial layer 50 is replaced with a metal portion 200 by embedding a metal in the portion where the sacrificial layer 50 was removed (second metal portion replacement operation S406).

As shown in FIG. 34, in the second metal portion replacement operation S406, a portion 53 of the remaining sacrificial layer 50 is accessed through the contact hole 180, and the portion 53 of the sacrificial layer 50 is removed. In addition, as shown in FIG. 35, in the second metal portion replacement operation S406, the metal portion 200 is embedded in the contact hole 180 and in a trench 190 formed by removing the portion 53 of the sacrificial layer 50. At this time, by forming the metal portion 200 so as to cover the first substrate surface 30a, the metal portion 60 previously formed from the second substrate surface 30b and the metal portion 200 subsequently formed from the first substrate surface 30a are connected by self-alignment. For this reason, a seamless metal portion 60, 200 can be easily formed.

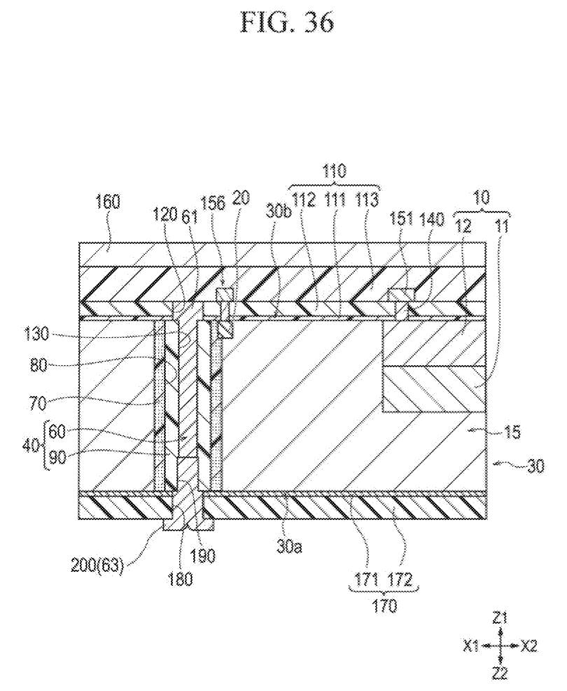

As shown in FIG. 36, the metal portion 200 is patterned on the first substrate surface 30a (metal portion patterning operation S407).

In the metal portion patterning operation S407, the metal portion 200 is removed so that a portion (the other end portion 63) of the metal portion 200 remains in a range overlapping with the isolation portion 40 in the height direction. The metal portion 200 after removal constitutes a portion (the other end portion 63) of the isolation portion 40 continuously connected to the metal portion 60 in the height direction. The metal portion 60, 200 thus formed has a shape in which the one end portion 61 located on the second substrate surface 30b and the other end portion 63 located on the first substrate surface 30a are widened in the width direction.

The manufacturing method according to an example embodiment, can provide a solid-state image sensor 1 that can effectively prevent the occurrence of crosstalk and at the same time achieve an improvement in DCR characteristics. In addition, it is possible to prevent the metal portion 60 from being exposed from the first substrate surface 30a in the process of replacing the sacrificial layer 50 with the metal portion 60. Thereby, it is possible to prevent the occurrence of white spots due to metal contamination or damage by the metal portion 60.

While aspects of example embodiments have been particularly shown and described, it will be understood that various changes in form and details may be made therein without departing from the spirit and scope of the following claims.

What is claimed is:

1. A method for manufacturing a solid-state image sensor including a photoelectric conversion portion, the method comprising:
forming a sacrificial layer in a trench extending from a second substrate surface of a substrate layer having a first substrate surface and the second substrate surface opposite to the first substrate surface;
forming the photoelectric conversion portion in the substrate layer from the second substrate surface;
removing the sacrificial layer; and
embedding a metal portion in the trench.

2. The method for manufacturing the solid-state image sensor of claim 1, further comprising performing a heat treatment operation before forming the photoelectric conversion portion.

3. The method for manufacturing the solid-state image sensor of claim 2, wherein the forming the sacrificial layer comprises:
forming the trench in the substrate layer from the second substrate surface;
forming an impurity layer on at least a sidewall of the trench from the second substrate surface;
forming a protection film on the impurity layer formed in the trench; and
disposing a material for forming the sacrificial layer in an inner peripheral portion of the protection film, and
wherein the heat treatment operation is performed after forming the impurity layer and before forming the photoelectric conversion portion.

4. The method for manufacturing the solid-state image sensor of claim 1, further comprising:
forming an insulation layer on the second substrate surface after forming the photoelectric conversion portion; and
forming a contact hole connected to the sacrificial layer in the insulation layer from the second substrate surface after forming the insulation layer,
wherein the metal portion extends into the contact hole.

5. The method for manufacturing the solid-state image sensor of claim 4, further comprising forming a metal wiring layer on the insulation layer after embedding the metal portion in the trench,
wherein the metal wiring layer is provided on one end of the metal portion located on the second substrate surface.

6. The method for manufacturing the solid-state image sensor of claim 5, further comprising forming a metal reflection layer on the insulation layer at a position corresponding to the photoelectric conversion portion.

7. The method for manufacturing the solid-state image sensor of claim 1, further comprising:
after forming the photoelectric conversion portion and before forming the metal portion, forming an insulation layer on the second substrate surface;
forming a metal wiring layer on the insulation layer; and
forming a contact hole in the insulation layer at a position corresponding to the sacrificial layer,
wherein the metal portion extends into the contact hole.

8. The method for manufacturing the solid-state image sensor of claim 1, wherein the sacrificial layer comprises polycrystalline silicon.

9. The method for manufacturing the solid-state image sensor of claim 1, wherein the metal portion comprises tungsten.

10. The method for manufacturing the solid-state image sensor of claim 1, wherein the solid-state image sensor is a back-side illuminated solid-state image sensor.

11. A method for manufacturing a solid-state image sensor including a photoelectric conversion portion, the method comprising:
forming a sacrificial layer in a trench extending from a second substrate surface of a substrate layer having a first substrate surface and the second substrate surface opposite to the first substrate surface;
forming the photoelectric conversion portion in the substrate layer from the second substrate surface;
removing a portion of the sacrificial layer from the second substrate surface;
embedding a first metal portion in the trench;
thinning the substrate layer from the first substrate surface to expose a portion of the sacrificial layer on the first substrate surface;
forming a protection layer covering the sacrificial layer on the first substrate surface;
forming a contact hole in the protection layer at a position corresponding to the sacrificial layer;
removing the sacrificial layer remaining in the substrate layer from the first substrate surface;
embedding a second metal portion in the trench from the first substrate surface a portion where the sacrificial layer was removed; and
patterning the second metal portion on the first substrate surface.

12. A solid-state image sensor comprising:
a substrate layer having a first substrate surface, a second substrate surface opposite to the first substrate surface, and a plurality of photoelectric conversion portions; and
an isolation portion between the plurality of photoelectric conversion portions,
wherein the isolation portion comprises:
a metal portion; and
a protection film on an outer side of the metal portion.

13. The solid-state image sensor of claim 12, wherein the metal portion extends along a first direction from the first substrate surface of the substrate layer past the second substrate surface.

14. The solid-state image sensor of claim 13, wherein a first end portion of the metal portion is coplanar with the first substrate surface of the substrate layer.

15. The solid-state image sensor of claim 13, wherein a second end portion of the metal portion that extends past the second substrate surface has a shape that protrudes or is narrowed in a second direction parallel to the second substrate surface of the substrate layer, compared to other parts of the metal portion.

16. The solid-state image sensor of claim 13, wherein the metal portion comprises tungsten.

17. The solid-state image sensor of claim 13, further comprising:
an anode electrode layer on the second substrate surface of the substrate layer; and
an impurity layer on an outer side of the protection film and in contact with the anode electrode layer,
wherein the anode electrode layer and the impurity layer are P-type semiconductor layers.

18. The solid-state image sensor of claim 17, wherein a length of the impurity layer along the first direction is equal to a length of the protection film along the first direction, and
wherein the length of the impurity layer along the first direction is shorter than a length of the metal portion along the first direction.

19. The solid-state image sensor of claim 12, further comprising an avalanche region within the plurality of photoelectric conversion portions,
wherein the avalanche region has a first semiconductor layer and a second semiconductor layer that are joined to form a PN junction.

20. The solid-state image sensor of claim 12, further comprising:
an anti-reflection film on the first substrate surface of the substrate layer; and
an insulation layer on the second substrate surface of the substrate layer.
